(19) United States
(12) Patent Application Publication
(10) Pub. No.: US 2026/0247813 A1
(43) Pub. Date: Aug. 20, 2026

(54) DISPLAY DEVICE AND ELECTRONIC DEVICE INCLUDING THE SAME

(71) Applicant: Samsung Display Co., Ltd., Yongin-si (KR)

(72) Inventors: Minki Yang, Yongin-si (KR); HYUNAE PARK, Yongin-si (KR); HEYJIN SHIN, Yongin-si (KR); CHANGKYU JIN, Yongin-si (KR)

(21) Appl. No.: 19/316,895

(22) Filed: Sep. 2, 2025

(30) Foreign Application Priority Data
Feb. 20, 2025 (KR) 10-2025-0022162

(51) Int. Cl. H10K 59/131; H10H 29/49; H10K 59/121

(52) U.S. Cl. CPC H10K 59/131; H10H 29/49; H10K 59/1216

(57) ABSTRACT

A display device includes a substrate, a first driving voltage transmission pattern above the substrate and configured to receive a driving voltage, a second driving voltage transmission pattern above the first driving voltage transmission pattern, extending in a first direction, and configured to receive the driving voltage, a driving voltage line above the second driving voltage transmission pattern, extending in a second direction crossing the first direction, and including a connection portion connected to the first driving voltage transmission pattern through a first contact hole and connected to the second driving voltage transmission pattern through a second contact hole, and a light-emitting element above the driving voltage line.

### CROSS-REFERENCE TO RELATED APPLICATION

The present application claims priority to, and the benefit of, Korean Patent Application No. 10-2025-0022162, filed on Feb. 20, 2025, in the Korean Intellectual Property Office, the entire disclosure of which is incorporated herein by reference.

### BACKGROUND

### 1. Field

The present disclosure relates generally to a display device that provides visual information and an electronic device including the display device.

### 2. Description of the Related Art

With the development of information technology, the importance of a display device, which is a connection medium between a user and information, has been highlighted. For example, the use of display devices, such as liquid crystal display (LCD) device, organic light emitting diode (OLED) display device, plasma display panel (PDP) device, quantum dot display device or the like is increasing.

### SUMMARY

Embodiments provide a display device with improved display quality.

Embodiments provide an electronic device including the display device.

A display device according to one or more embodiments of the present disclosure includes a substrate, a first driving voltage transmission pattern above the substrate and configured to receive a driving voltage, a second driving voltage transmission pattern above the first driving voltage transmission pattern, extending in a first direction, and configured to receive the driving voltage, a driving voltage line above the second driving voltage transmission pattern, extending in a second direction crossing the first direction, and including a connection portion connected to the first driving voltage transmission pattern through a first contact hole and connected to the second driving voltage transmission pattern through a second contact hole, and a light-emitting element above the driving voltage line.

The connection portion of the driving voltage line may include a first extension portion extending in the first direction and a second extension portion extending in the second direction.

The second extension portion may be connected to the first driving voltage transmission pattern and to the second driving voltage transmission pattern through the first contact hole and through the second contact hole, respectively.

The connection portion of the driving voltage line may be substantially U-shaped in a plan view.

The first driving voltage transmission pattern and the second driving voltage transmission pattern may be spaced apart from each other in a plan view.

The driving voltage line may be provided as a plurality of driving voltage lines spaced apart in the first direction.

The first driving voltage transmission pattern may connect adjacent ones of the driving voltage lines.

The first driving voltage transmission pattern may be provided as a plurality of first driving voltage transmission patterns spaced apart from each other in the first direction.

The display device may further include a capacitor pattern at a same layer as the first driving voltage transmission pattern, spaced apart from the first driving voltage transmission pattern in a plan view, and having capacitance with a portion of the second driving voltage transmission pattern overlapping the capacitor pattern.

The display device may further include an active pattern above the substrate, a gate electrode above the active pattern, a first capacitor electrode above the gate electrode, a second capacitor electrode above the first capacitor electrode, and a source electrode at a layer above the second capacitor electrode.

The first driving voltage transmission pattern may be at a same layer as the first capacitor electrode, wherein the second driving voltage transmission pattern is at a same layer as the second capacitor electrode.

The driving voltage line may be at a same layer as the source electrode.

A first overlap area between the first driving voltage transmission pattern and the driving voltage line may be less than a second overlap area between the second driving voltage transmission pattern and the driving voltage line.

A display device according to one or more embodiments of the present disclosure includes a substrate, a first driving voltage transmission pattern above the substrate, configured to receive a driving voltage, and including a first path configured to transmit the driving voltage in a first direction, a second driving voltage transmission pattern above the first driving voltage transmission pattern, configured to receive the driving voltage, and including a second path configured to transmit the driving voltage in the first direction, a driving voltage line above the second driving voltage transmission pattern, extending in a second direction crossing the first direction, and including a connection portion connected to the first driving voltage transmission pattern through a first contact hole and connected to the second driving voltage transmission pattern through a second contact hole, and a light-emitting element above the driving voltage line.

The connection portion of the driving voltage line may include a first extension portion extending in the first direction and a second extension portion extending in the second direction.

The second extension portion may be connected to the first driving voltage transmission pattern and to the second driving voltage transmission pattern through the first contact hole and through the second contact hole, respectively.

The driving voltage line may be provided as a plurality of driving voltage lines spaced apart from each other in the first direction, wherein the first driving voltage transmission pattern connects adjacent driving voltage lines.

The first driving voltage transmission pattern and the second driving voltage transmission pattern may be spaced apart from each other in a plan view.

The display device may further include a capacitor pattern at a same layer as the first driving voltage transmission pattern, spaced apart from the first driving voltage transmission pattern in a plan view, and having capacitance with a portion of the second driving voltage transmission pattern overlapping the capacitor pattern.

An electronic device according to one or more embodiments of the present disclosure includes a processor configured to transmit an image data signal and an input control signal, and a display device configured to receive the image data signal and the input control signal, and including a substrate, a first driving voltage transmission pattern above the substrate and configured to receive a driving voltage, a second driving voltage transmission pattern above the first driving voltage transmission pattern, extending in a first direction, and configured to receive the driving voltage, a driving voltage line above the second driving voltage transmission pattern, extending in a second direction crossing the first direction, and including a connection portion connected to the first driving voltage transmission pattern through a first contact hole and connected to the second driving voltage transmission pattern through a second contact hole, and the light-emitting element above the driving voltage line.

According to embodiments of the present disclosure, to transmit a driving voltage in a first direction, the display device may include a plurality of transmission patterns that are located in different layers and that receive the driving voltage. For example, the display device may include a first driving voltage transmission pattern, a second driving voltage transmission pattern located on the first driving voltage transmission pattern, and a driving voltage line located on the second driving voltage transmission pattern. Each of the first driving voltage transmission pattern, the second driving voltage transmission pattern, and the driving voltage line may transmit the driving voltage in the first direction. In other words, the driving voltage may be transmitted in the first direction through a plurality of voltage transmission paths.

Accordingly, compared to a case where the driving voltage is transmitted in the first direction through a single voltage transmission path, a resistance occurring in the transmission patterns (or lines) transmitting the driving voltage may be effectively reduced. As a result, a luminance difference between pixels caused by the resistance may be reduced, a defect in which a stain is recognized in the display device may be reduced or prevented, and the display quality of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to one or more embodiments of the present disclosure.

FIG. 2A is a plan view illustrating an example of the display device of FIG. 1.

FIG. 2B is a plan view illustrating another example of the display device of FIG. 1.

FIG. 3A is a circuit diagram illustrating an example of a circuit structure of a pixel included in the display device of FIG. 1.

FIG. 3B is a circuit diagram illustrating another example of a circuit structure of a pixel included in the display device of FIG. 1.

FIG. 4 is a cross-sectional view illustrating a display panel included in the display device of FIG. 1.

FIGS. 5, 6, 7, 8, 9, 10, 11, 12, and 13 are layout views illustrating an example of a pixel included in the display device of FIG. 1.

FIG. 14 is a layout view for describing a path through which a driving voltage is transmitted in a first direction.

FIG. 15 is a block diagram illustrating an electronic device according to one or more embodiments of the present disclosure.

FIG. 16 is a schematic view of an electronic device according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

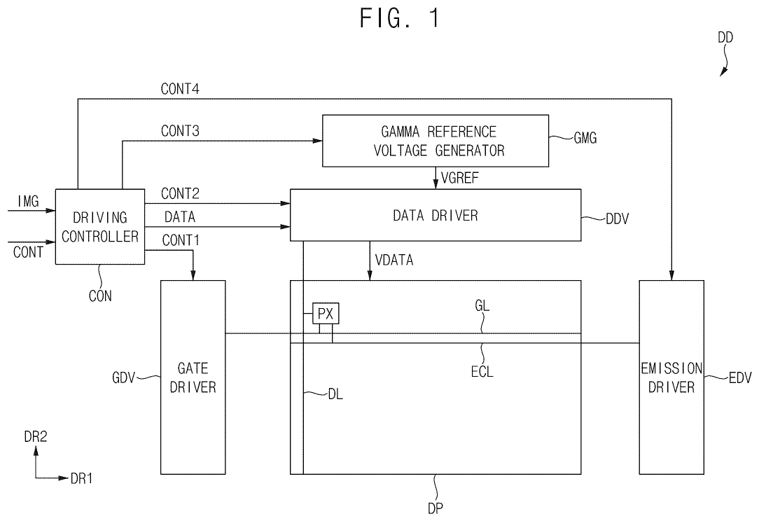

FIG. 1 is a block diagram illustrating a display device according to one or more embodiments of the present disclosure.

Referring to FIG. 1, a display device DD according to one or more embodiments of the present disclosure may include a display panel DP, and a panel driver that drives the display panel DP. The panel driver may include a driving controller CON, a gate driver GDV, a gamma reference voltage generator GMG, a data driver DDV, and an emission driver EDV.

For example, the driving controller CON and the data driver DDV may be integrally formed. A driving module, in which the driving controller CON and the data driver DDV are integrally formed, may be referred to as a timing-controller-embedded data driver (TED).

The display panel DP may include gate lines GL, emission lines ECL, data lines DL, and pixels PX. The pixels PX may be electrically connected to the gate lines GL, the emission lines ECL, and the data lines DL. Each of the pixels PX may generate light in response to a driving signal. For example, each of the gate lines GL may extend in a first direction DR1, and each of the emission lines ECL may extend in the first direction DR1. Each of the data lines DL may extend in a second direction DR2 crossing the first direction DR1. For example, the first direction DR1 and the second direction DR2 may be perpendicular to each other.

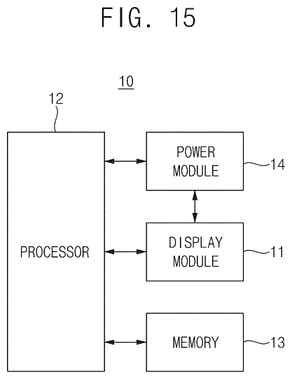

The driving controller CON may receive an image data signal IMG and an input control signal CONT from an external device (e.g., a processor 12 of FIG. 15). For example, the image data signal IMG may include red image data, green image data, and blue image data. In one or more embodiments, the image data signal IMG may further include white image data. The input control signal CONT may include a vertical synchronization signal, a horizontal synchronization signal, a data enable signal, a master clock signal, or the like.

The driving controller CON may generate a first control signal CONT1, a second control signal CONT2, a third control signal CONT3, a fourth control signal CONT4, and a data signal DATA based on the image data signal IMG and the input control signal CONT.

The driving controller CON may output the first control signal CONT1 to the gate driver GDV. The first control signal CONT1 may include a vertical start signal and a gate clock signal. The driving controller CON may output the second control signal CONT2 and the data signal DATA to the data driver DDV. The second control signal CONT2 may include a horizontal start signal and a load signal. The driving controller CON may output the third control signal CONT3 to the gamma reference voltage generator GMG. The driving controller CON may output the fourth control signal CONT4 to the emission driver EDV.

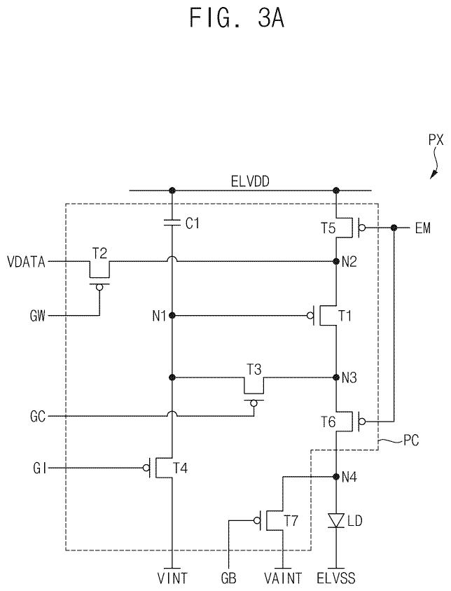

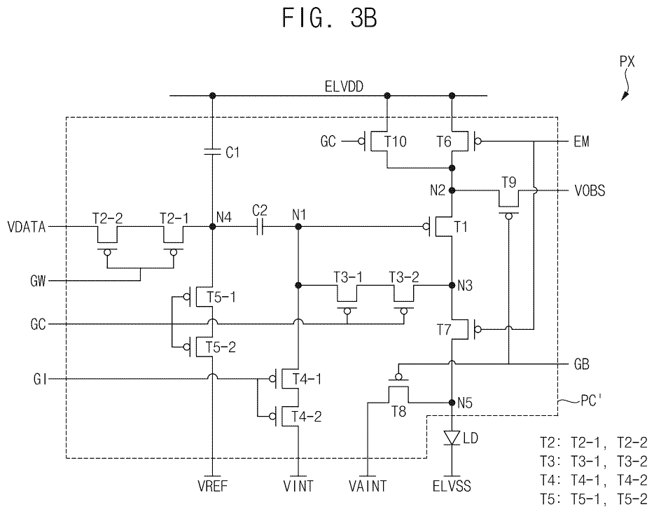

The gate driver GDV may generate gate signals in response to the first control signal CONT1. The gate driver GDV may output the gate signals to the gate lines GL. In one or more embodiments, the gate signals may include first to fourth gate signals GW, GC, GI, and GB illustrated in FIGS. 3A and 3B. However, the present disclosure is not necessarily limited thereto.

The gamma reference voltage generator GMG may generate a gamma reference voltage VGREF in response to the third control signal CONT3. The gamma reference voltage generator GMG may provide the gamma reference voltage VGREF to the data driver DDV. For example, the gamma reference voltage generator GMG may be located in the driving controller CON or may be located in the data driver DDV.

The data driver DDV may receive the second control signal CONT2 and the data signal DATA from the driving controller CON, and may receive the gamma reference voltage VGREF from the gamma reference voltage generator GMG. The data driver DDV may convert the data signal DATA into an analog form of a data voltage VDATA using the gamma reference voltage VGREF. The data driver DDV may output the data voltage VDATA to the data lines DL.

The emission driver EDV may generate emission signals in response to the fourth control signal CONT4. The emission driver EDV may output the emission signals to the emission lines ECL. In one or more embodiments, the emission signals may include an emission control signal EM illustrated in FIGS. 3A and 3B. However, the present disclosure is not necessarily limited thereto.

In FIG. 1, for convenience of description, the gate driver GDV is illustrated as being located at a first side of the display panel DP and the emission driver EDV is illustrated as being located at a second side opposite to the first side of the display panel DP, but the present disclosure is not necessarily limited thereto. For example, both the gate driver GDV and the emission driver EDV may be located at the first side of the display panel DP. For example, both the gate driver GDV and the emission driver EDV may be respectively located at opposite sides of the display panel DP. For example, the gate driver GDV and the emission driver EDV may be integrally formed.

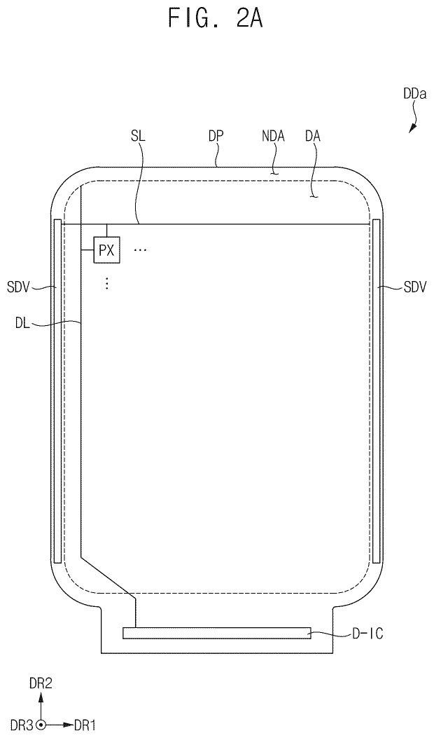

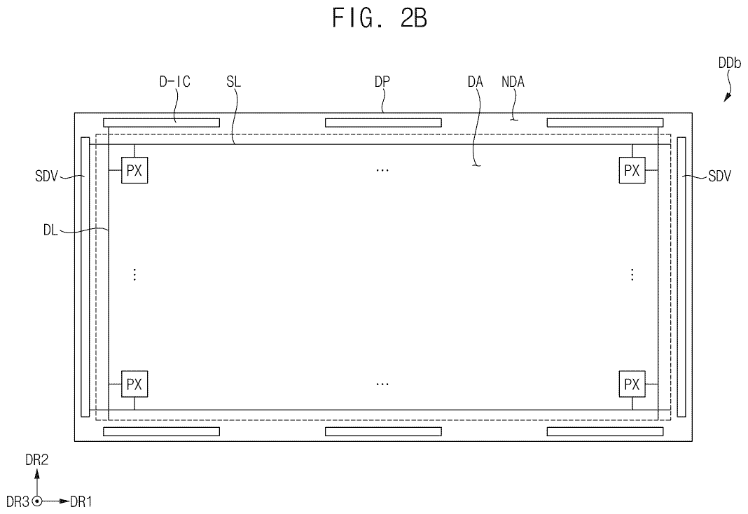

FIG. 2A is a plan view illustrating an example of the display device of FIG. 1. FIG. 2B is a plan view illustrating another example of the display device of FIG. 1.

In this specification, a plane may be defined by the first direction DR1 and the second direction DR2. A direction normal to the plane may be a third direction DR3. In other words, the third direction DR3 may be perpendicular to each of the first direction DR1 and the second direction DR2. As used herein the “plan view” is a view in the third direction DR3.

Referring to FIGS. 2A and 2B, each of display devices DDa and DDb may be a device that is activated in response to an electrical signal. For example, the display device DDa may be a small display device used in small electronic devices, such as a smartphone, a cell phone, a smart watch, a game console, and a camera. In addition, the display device DDb may be a medium-to large-sized display device used for medium-to large-sized electronic devices, such as a laptop, a tablet PC, a television, a computer monitor, a vehicle monitor, and an exterior billboard. In FIG. 2A, the display device DDa is illustrated as an example of the small display device, and in FIG. 2B, the display device DDb is illustrated as an example of the medium-to large-sized display device.

Each of the display devices DDa and DDb may include a display area DA and a peripheral area NDA. The display area DA may be an area that displays an image by generating light or adjusting the transmittance of light provided from an external light source. The peripheral area NDA may be located around the display area DA. For example, the peripheral area NDA may surround at least a portion of the display area DA (e.g., in plan view). In one or more embodiments, the peripheral area NDA may be an area that does not display an image. However, the present disclosure is not necessarily limited thereto, and an image may be displayed in at least a portion of the peripheral area NDA.

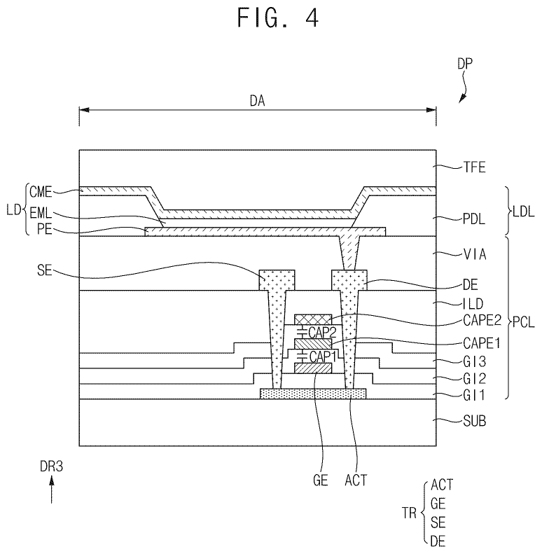

Each of the display devices DDa and DDb may include the display panel DP, a scan driver SDV, and a driving chip D-IC, and the display panel DP may include a substrate (SUB, see FIG. 4), the pixels PX, scan lines SL, and the data lines DL.

The substrate may form a base of each of the display devices DDa and DDb. In one or more embodiments, examples of a material that may be used as the substrate may include glass, quartz, silicon, polymer, or the like. These may be used alone or in combination with each other.

The pixels PX may be located in the display area DA on the substrate. The pixels PX may be electrically connected to the scan line SL and the data line DL. Here, the scan line SL may correspond to the gate line GL or emission line ECL of FIG. 1. For example, the pixels PX may be located in a matrix form along the first direction DR1 and the second direction DR2.

Each of the pixels PX may include a plurality of sub-pixels. For example, each of the pixels PX may include a first sub-pixel, a second sub-pixel, and a third sub-pixel. Each of the first to third sub-pixels may include a light-emitting element and a pixel-driving circuit connected to the light-emitting element. The light-emitting element may emit light. In one or more embodiments, the first to third sub-pixels may emit light of different wavelength bands. That is, the first to third sub-pixels may emit light of different respective colors. For example, the first sub-pixel may emit red light, the second sub-pixel may emit green light, and the third sub-pixel may emit blue light. However, the present disclosure is not necessarily limited thereto.

The driving chip D-IC may be located in the peripheral area NDA on the substrate. The driving chip D-IC may correspond to the data driver DDV of FIG. 1. That is, the driving chip D-IC may output the data voltage (VDATA, see FIG. 1) to the data line DL. The data voltage may be applied to the pixels PX through the data line DL.

In one or more embodiments, the driving chip D-IC may be mounted on the substrate. However, the present disclosure is not necessarily limited thereto, and the driving chip D-IC may be located on a flexible film bonded to the substrate in the form of a chip on film (COF).

In one or more embodiments, the display device DDb of FIG. 2B may include a plurality of driving chips D-IC. For example, the driving chips D-IC may be located at opposite sides of the display area DA in the second direction DR2. For example, the driving chips D-IC may be located along a long side of the display device DDb. However, the present disclosure is not necessarily limited thereto.

The scan driver SDV may be located in the peripheral area NDA on the substrate. The scan driver SDV may correspond to the gate driver GDV or the emission driver EDV of FIG. 1. For example, the scan driver SDV may output the gate signal to the scan line SL. The gate signal may be applied to the pixels PX through the scan line SL. For example, the scan driver SDV may output the emission signal to the scan line SL. The emission signal may be applied to the pixels PX through the scan line SL.

In one or more embodiments, the scan driver SDV may be located at opposite sides of the display area DA in the first direction DR1. However, the present disclosure is not necessarily limited thereto.

The number or arrangement relationship of the driving chips D-IC and the number or arrangement relationship of the scan driver SDV illustrated in FIGS. 2A and 2B are only examples, and the present disclosure is not necessarily limited thereto.

In addition, although the display device DDa is illustrated in FIG. 2A as having a substantially rectangular planar shape having a short side extending in the first direction DR1 and a long side extending in the second direction DR2, the present disclosure is not necessarily limited thereto. In addition, although the display device DDb is illustrated in FIG. 2B as having a substantially rectangular planar shape having a long side extending in the first direction DR1 and a short side extending in the second direction DR2, the present disclosure is not necessarily limited thereto. That is, the planar shape of each of the display devices DDa and DDb may be changed in various ways according to embodiments.

The following descriptions with reference to the following drawings can be equally applied to the display device DDa of FIG. 2A and the display device DDb of FIG. 2B. Hereinafter, for convenience of description, the expression is unified as the display device DD.

FIG. 3A is a circuit diagram illustrating an example of a circuit structure of a pixel included in the display device of FIG. 1. For example, FIG. 3A is a circuit diagram of any one of the first to third sub-pixels included in the pixel PX.

Referring to FIG. 3A, the pixel PX may include the first to third sub-pixels, and the first to third sub-pixels may have substantially the same circuit structure as each other. Each of the first to third sub-pixels may include a light-emitting element LD and a pixel-driving circuit PC connected to the light-emitting element LD. The pixel-driving circuit PC may generate a driving current, and the light-emitting element LD may generate light based on the driving current.

The pixel-driving circuit PC may include at least one transistor and at least one capacitor. In one or more embodiments, the pixel-driving circuit PC may include first to seventh transistors T1, T2, T3, T4, T5, T6, and T7 and a first capacitor C1. Each of the first to seventh transistors T1, T2, T3, T4, T5, T6, and T7 may be a metal oxide semiconductor field effect transistor (MOSFET) formed by a semiconductor process.

In FIG. 3A, the first to seventh transistors T1, T2, T3, T4, T5, T6, and T7 are illustrated as p-type transistors, but the present disclosure is not necessarily limited thereto. For example, each of the first transistor T1, the second transistor T2, the fifth transistor T5, the sixth transistor T6, and the seventh transistor T7 may be a p-type transistor, and each of the third transistor T3 and the fourth transistor T4 may be an n-type transistor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide a driving current to the light-emitting element LD. For example, the first transistor T1 may be referred to as a driving transistor.

The second transistor T2 may include a gate electrode, a first electrode, and a second electrode. The gate electrode of the second transistor T2 may receive a first gate signal GW. The first electrode of the second transistor T2 may receive the data voltage VDATA. The second electrode of the second transistor T2 may be connected to the second node N2. The second transistor T2 may be turned on or off in response to the first gate signal GW. While the second transistor T2 is turned on, the second transistor T2 may provide the data voltage VDATA to the second node N2. For example, the second transistor T2 may be referred to as a write transistor.

The third transistor T3 may include a gate electrode, a first electrode, and a second electrode. The gate electrode of the third transistor T3 may receive a second gate signal GC. The first electrode of the third transistor T3 may be connected to the first node N1. The second electrode of the third transistor T3 may be connected to the third node N3. The third transistor T3 may be turned on or off in response to the second gate signal GC. While the third transistor T3 is turned on, the third transistor T3 may diode-connect the first transistor T1. That is, the third transistor T3 may form a path for compensating a threshold voltage of the first transistor T1. For example, the third transistor T3 may be referred to as a compensation transistor.

The fourth transistor T4 may include a gate electrode, a first electrode, and a second electrode. The gate electrode of the fourth transistor T4 may receive a third gate signal GI. The first electrode of the fourth transistor T4 may receive a first initialization voltage VINT. The second electrode of the fourth transistor T4 may be connected to the first node N1. The fourth transistor T4 may be turned on or off in response to the third gate signal GI. While the fourth transistor T4 is turned on, the fourth transistor T4 may provide the first initialization voltage VINT to the first node N1. Accordingly, the fourth transistor T4 may provide the first initialization voltage VINT to the gate electrode of the first transistor T1 to initialize a voltage of the gate electrode of the first transistor T1. For example, the fourth transistor T4 may be referred to as a gate initialization transistor.

The fifth transistor T5 may include a gate electrode, a first electrode, and a second electrode. The gate electrode of the fifth transistor T5 may receive an emission control signal EM. The first electrode of the fifth transistor T5 may receive a driving voltage ELVDD having a relatively high level of voltage. The second electrode of the fifth transistor T5 may be connected to the second node N2. The fifth transistor T5 may be turned on or off in response to the emission control signal EM. While the fifth transistor T5 is turned on, the fifth transistor T5 may provide the driving voltage ELVDD to the second node N2. For example, the fifth transistor T5 may be referred to as a first emission control transistor.

The sixth transistor T6 may include a gate electrode, a first electrode, and a second electrode. The gate electrode of the sixth transistor T6 may receive the emission control signal EM. The first electrode of the sixth transistor T6 may be connected to the third node N3. The second electrode of the sixth transistor T6 may be connected to a fourth node N4. The sixth transistor T6 may be turned on or off in response to the emission control signal EM. While the sixth transistor T6 is turned on, the sixth transistor T6 may electrically connect the second electrode of the first transistor T1 and an anode of the light-emitting element LD. Accordingly, the sixth transistor T6 may provide the driving current to the light-emitting element LD. For example, the sixth transistor T6 may be referred to as a second emission control transistor.

Although the fifth transistor T5 and the sixth transistor T6 are illustrated in FIG. 3A as being concurrently or substantially simultaneously driven by the substantially single emission control signal EM, the present disclosure is not necessarily limited thereto. For example, the fifth transistor T5 and the sixth transistor T6 may be driven independently by different emission control signals.

The seventh transistor T7 may include a gate electrode, a first electrode, and a second electrode. The gate electrode of the seventh transistor T7 may receive a fourth gate signal GB. The first electrode of the seventh transistor T7 may receive a second initialization voltage VAINT. The second electrode of the seventh transistor T7 may be connected to the fourth node N4. The seventh transistor T7 may be turned on or off in response to the fourth gate signal GB. While the seventh transistor T7 is turned on, the seventh transistor T7 may provide the second initialization voltage VAINT to the fourth node N4. Accordingly, the seventh transistor T7 may provide the second initialization voltage VAINT to the anode of the light-emitting element LD to initialize a voltage of the anode. For example, the seventh transistor T7 may be referred to as an anode initialization transistor.

The first capacitor C1 may include a first electrode and a second electrode. The first electrode of the first capacitor C1 may receive the driving voltage ELVDD. The second electrode of the first capacitor C1 may be connected to the first node N1.

The light-emitting element LD may include the anode and a cathode. The anode of the light-emitting element LD may be connected to the fourth node N4. The cathode of the light-emitting element LD may receive a common voltage ELVSS having a relatively low level of voltage. That is, a voltage level of the common voltage ELVSS may be lower than a voltage level of the driving voltage ELVDD. The light-emitting element LD may generate light having a luminance corresponding to the driving current.

In FIG. 3A, the pixel-driving circuit PC is illustrated as including seven transistors and one capacitor, but the present disclosure is not necessarily limited thereto.

FIG. 3B is a circuit diagram illustrating another example of a circuit structure of a pixel included in the display device of FIG. 1. For example, FIG. 3B is a circuit diagram of any one of the first to third sub-pixels included in the pixel PX.

Referring to FIG. 3B, the pixel PX may include the first to third sub-pixels, and the first to third sub-pixels may have substantially the same circuit structure as each other. Each of the first to third sub-pixels may include the light-emitting element LD and a pixel-driving circuit PC′ connected to the light-emitting element LD.

The pixel-driving circuit PC′ may include at least one transistor and at least one capacitor. In one or more embodiments, the pixel-driving circuit PC′ may include first to tenth transistors T1, T2, T3, T4, T5, T6, T7, T8, T9, and T10, a first capacitor C1, and a second capacitor C2. In FIG. 3B, the first to tenth transistors T1, T2, T3, T4, T5, T6, T7, T8, T9, and T10 are all illustrated as p-type transistors, but the present disclosure is not necessarily limited thereto.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide a driving current to the light-emitting element LD. The first transistor T1 of FIG. 3B may correspond to the first transistor T1 of FIG. 3A.

The second transistor T2 may include a gate electrode, a first electrode, and a second electrode. The gate electrode of the second transistor T2 may receive a first gate signal GW. The first electrode of the second transistor T2 may receive the data voltage VDATA. The second electrode of the second transistor T2 may be connected to a fourth node N4. The second transistor T2 may be turned on or off in response to the first gate signal GW. While the second transistor T2 is turned on, the second transistor T2 may provide the data voltage VDATA to the fourth node N4. The second transistor T2 of FIG. 3B may correspond to the second transistor T2 of FIG. 3A.

In one or more embodiments, the second transistor T2 may have a dual transistor structure in which two transistors are connected in series. For example, the second transistor T2 may include a (2-1)-th transistor T2-1 and a (2-2)-th transistor T2-2 that are connected in series. In other words, a gate electrode of the (2-1)-th transistor T2-1 and a gate electrode of the (2-2)-th transistor T2-2 may be connected, and a first electrode of the (2-1)-th transistor T2-1 and a second electrode of the (2-2)-th transistor T2-2 may be connected. However, the present disclosure is not necessarily limited thereto, and the second transistor T2 may have a single transistor structure.

The third transistor T3 may include a gate electrode, a first electrode, and a second electrode. The gate electrode of the third transistor T3 may receive a second gate signal GC. The first electrode of the third transistor T3 may be connected to the first node N1. The second electrode of the third transistor T3 may be connected to the third node N3. The third transistor T3 may be turned on or off in response to the second gate signal GC. While the third transistor T3 is turned on, the third transistor T3 may diode-connect the first transistor T1. The third transistor T3 of FIG. 3B may correspond to the third transistor T3 of FIG. 3A.

In one or more embodiments, the third transistor T3 may have a dual transistor structure in which two transistors are connected in series. For example, the third transistor T3 may include a (3-1)-th transistor T3-1 and a (3-2)-th transistor T3-2 that are connected in series. In other words, a gate electrode of the (3-1)-th transistor T3-1 and a gate electrode of the (3-2)-th transistor T3-2 may be connected, and a second electrode of the (3-1)-th transistor T3-1 and a first electrode of the (3-2)-th transistor T3-2 may be connected. However, the present disclosure is not necessarily limited thereto, and the third transistor T3 may have a single transistor structure.

The fourth transistor T4 may include a gate electrode, a first electrode, and a second electrode. The gate electrode of the fourth transistor T4 may receive a third gate signal GI. The first electrode of the fourth transistor T4 may receive a first initialization voltage VINT. The second electrode of the fourth transistor T4 may be connected to the first node N1. The fourth transistor T4 may be turned on or off in response to the third gate signal GI. While the fourth transistor T4 is turned on, the fourth transistor T4 may provide the first initialization voltage VINT to the first node N1. Accordingly, the fourth transistor T4 may initialize a voltage of the gate electrode of the first transistor T1. The fourth transistor T4 of FIG. 3B may correspond to the fourth transistor T4 of FIG. 3A.

In one or more embodiments, the fourth transistor T4 may have a dual transistor structure in which two transistors are connected in series. For example, the fourth transistor T4 may include a (4-1)-th transistor T4-1 and a (4-2)-th transistor T4-2 that are connected in series. In other words, a gate electrode of the (4-1)-th transistor T4-1 and a gate electrode of the (4-2)-th transistor T4-2 may be connected, and a first electrode of the (4-1)-th transistor T4-1 and a second electrode of the (4-2)-th transistor T4-2 may be connected. However, the present disclosure is not necessarily limited thereto, and the fourth transistor T4 may have a single transistor structure.

The fifth transistor T5 may include a gate electrode, a first electrode, and a second electrode. The gate electrode of the fifth transistor T5 may receive the second gate signal GC. The first electrode of the fifth transistor T5 may receive a reference voltage VREF. The second electrode of the fifth transistor T5 may be connected to the fourth node N4. The fifth transistor T5 may be turned on or off in response to the second gate signal GC. While the fifth transistor T5 is turned on, the fifth transistor T5 may provide the reference voltage VREF to the fourth node N4.

In one or more embodiments, the fifth transistor T5 may have a dual transistor structure in which two transistors are connected in series. For example, the fifth transistor T5 may include a (5-1)-th transistor T5-1 and a (5-2)-th transistor T5-2 that are connected in series. In other words, a gate electrode of the (5-1)-th transistor T5-1 and a gate electrode of the (5-2)-th transistor T5-2 may be connected, and a first electrode of the (5-1)-th transistor T5-1 and a second electrode of the (5-2)-th transistor T5-2 may be connected. However, the present disclosure is not necessarily limited thereto, and the fifth transistor T5 may have a single transistor structure.

The sixth transistor T6 may include a gate electrode, a first electrode, and a second electrode. The gate electrode of the sixth transistor T6 may receive an emission control signal EM. The first electrode of the sixth transistor T6 may receive a driving voltage ELVDD having a relatively high level of voltage. The second electrode of the sixth transistor T6 may be connected to the second node N2. The sixth transistor T6 may be turned on or off in response to the emission control signal EM. While the sixth transistor T6 is turned on, the sixth transistor T6 may provide the driving voltage ELVDD to the second node N2. The sixth transistor T6 of FIG. 3B may correspond to the fifth transistor T5 of FIG. 3A.

The seventh transistor T7 may include a gate electrode, a first electrode, and a second electrode. The gate electrode of the seventh transistor T7 may receive the emission control signal EM. The first electrode of the seventh transistor T7 may be connected to the third node N3. The second electrode of the seventh transistor T7 may be connected to a fifth node N5. The seventh transistor T7 may be turned on or off in response to the emission control signal EM. While the seventh transistor T7 is turned on, the seventh transistor T7 may electrically connect the second electrode of the first transistor T1 and an anode of the light-emitting element LD. The seventh transistor T7 of FIG. 3B may correspond to the sixth transistor T6 of FIG. 3A.

The eighth transistor T8 may include a gate electrode, a first electrode, and a second electrode. The gate electrode of the eighth transistor T8 may receive a fourth gate signal GB. The first electrode of the eighth transistor T8 may receive a second initialization voltage VAINT. The second electrode of the eighth transistor T8 may be connected to the fifth node N5. The eighth transistor T8 may be turned on or off in response to the fourth gate signal GB. While the eighth transistor T8 is turned on, the eighth transistor T8 may provide the second initialization voltage VAINT to the fifth node N5. Accordingly, the eighth transistor T8 may initialize a voltage of the anode of the light-emitting element LD. The eighth transistor T8 of FIG. 3B may correspond to the seventh transistor T7 of FIG. 3A.

The ninth transistor T9 may include a gate electrode, a first electrode, and a second electrode. The gate electrode of the ninth transistor T9 may receive the fourth gate signal GB. The first electrode of the ninth transistor T9 may receive a bias voltage VOBS. The second electrode of the ninth transistor T9 may be connected to the second node N2. The ninth transistor T9 may be turned on or off in response to the fourth gate signal GB. While the ninth transistor T9 is turned on, the ninth transistor T9 may provide the bias voltage VOBS to the second node N2.

The tenth transistor T10 may include a gate electrode, a first electrode, and a second electrode. The gate electrode of the tenth transistor T10 may receive the second gate signal GC. The first electrode of the tenth transistor T10 may receive the driving voltage ELVDD. The second electrode of the tenth transistor T10 may be connected to the second node N2. The tenth transistor T10 may be turned on or off in response to the second gate signal GC. While the tenth transistor T10 is turned on, the tenth transistor T10 may provide the driving voltage ELVDD to the second node N2.

The first capacitor C1 may include a first electrode and a second electrode. The first electrode of the first capacitor C1 may receive the driving voltage ELVDD. The second electrode of the first capacitor C1 may be connected to the fourth node N4. For example, the first capacitor C1 may be referred to as a storage capacitor.

The second capacitor C2 may include a first electrode and a second electrode. The first electrode of the second capacitor C2 may be connected to the first node N1. The second electrode of the second capacitor C2 may be connected to the fourth node N4. For example, the second capacitor C2 may be referred to as a hold capacitor.

The light-emitting element LD may include the anode and a cathode. The anode of the light-emitting element LD may be connected to the fifth node N5. The cathode of the light-emitting element LD may receive a common voltage ELVSS having a relatively low level of voltage. That is, a voltage level of the common voltage ELVSS may be lower than a voltage level of the driving voltage ELVDD. The light-emitting element LD may generate light having a luminance corresponding to the driving current.

In one or more embodiments, the pixel-driving circuit PC′ may further include an emission capacitor connected in parallel with the light-emitting element LD. The emission capacitor may include a first electrode and a second electrode. The first electrode of the emission capacitor may be connected to the fifth node N5. The second electrode of the emission capacitor may receive the common voltage ELVSS.

In FIG. 3B, the pixel-driving circuit PC′ is illustrated as including 10 transistors and 2 capacitors, but the present disclosure is not necessarily limited thereto.

FIG. 4 is a cross-sectional view illustrating a display panel included in the display device of FIG. 1. For example, FIG. 4 is a cross-sectional view illustrating a cross-sectional structure of one sub-pixel included in the pixel PX of FIG. 1.

Referring to FIG. 4, the display panel DP may include a substrate SUB, a circuit element layer PCL located on the substrate SUB, a light-emitting element layer LDL located on the circuit element layer PCL, and an encapsulation layer TFE located on the light-emitting element layer LDL (as used herein, “located on” may mean “above”). The circuit element layer PCL may include a thin film transistor TR, a first gate-insulating layer GI1, a second gate-insulating layer GI2, a first capacitor electrode CAPE1, a third gate-insulating layer GI3, a second capacitor electrode CAPE2, an inter-layer insulating layer ILD, and a via-insulating layer VIA. The light-emitting element layer LDL may include the light-emitting element LD and a pixel-defining layer PDL.

The thin film transistor TR may include an active pattern ACT, a gate electrode GE, a source electrode SE, and a drain electrode DE. The light-emitting element LD may include a pixel electrode PE, a light-emitting layer EML, and a common electrode CME.

The thin-film transistor TR of FIG. 4 may be a transistor connected to the light-emitting element LD. For example, the thin film transistor TR may be the sixth transistor T6 of FIG. 3A or the seventh transistor T7 of FIG. 3B.

The active pattern ACT may be located on the substrate SUB. The active pattern ACT may include a silicon semiconductor material, an oxide semiconductor material, an organic semiconductor material, or the like. In one or more embodiments, the active pattern ACT may include a silicon semiconductor material. The silicon semiconductor material may include amorphous silicon, polycrystalline silicon, or the like. The active pattern ACT may include a source area, a drain area, and a channel area between the source area and the drain area.

The first gate-insulating layer GI1 may be located on the substrate SUB and the active pattern ACT. The first gate-insulating layer GI1 may cover the active pattern ACT. For example, the first gate-insulating layer GI1 may be located along the profile of the active pattern ACT with a substantially uniform thickness, but the present disclosure is not necessarily limited thereto. The first gate-insulating layer GI1 may include an inorganic insulating material. Examples of the inorganic insulating material that may be used as the first gate-insulating layer GI1 may include silicon oxide (SiOₓ), silicon nitride (SiNₓ), silicon oxynitride (SiOₓN_{y}), or the like. These may be used alone or in combination with each other.

The gate electrode GE may be located on the first gate-insulating layer GI1. The gate electrode GE may overlap the active pattern ACT in a plan view. In addition, the gate electrode GE may overlap the channel area of the active pattern ACT. The gate electrode GE may include a conductive material, such as a metal, an alloy, a conductive metal nitride, a conductive metal oxide, a transparent conductive oxide, or the like. Examples of the conductive material may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The second gate-insulating layer GI2 may be located on the first gate-insulating layer GI1. The second gate-insulating layer GI2 may cover the gate electrode GE. For example, the second gate-insulating layer GI2 may be located along the profile of the gate electrode GE with a substantially uniform thickness, but the present disclosure is not necessarily limited thereto. The second gate-insulating layer GI2 may include an inorganic insulating material. Examples of the inorganic insulating material that may be used as the second gate-insulating layer GI2 may include silicon oxide (SiOₓ), silicon nitride (SiNₓ), silicon oxynitride (SiOₓN_{y}), or the like. These may be used alone or in combination with each other.

The first capacitor electrode CAPE1 may be located on the second gate-insulating layer GI2. The first capacitor electrode CAPE1 may overlap the gate electrode GE in a plan view. The first capacitor electrode CAPE1 may be spaced apart from the gate electrode GE by the second gate-insulating layer GI2. The gate electrode GE and the first capacitor electrode CAPE1 may form a first capacitor CAP1. The first capacitor electrode CAPE1 may include a conductive material, such as a metal, an alloy, a conductive metal nitride, a conductive metal oxide, a transparent conductive oxide, or the like. These may be used alone or in combination with each other.

The third gate-insulating layer GI3 may be located on the second gate-insulating layer GI2. The third gate-insulating layer GI3 may cover the first capacitor electrode CAPE1. For example, the third gate-insulating layer GI3 may be located along the profile of the first capacitor electrode CAPE1 with a substantially uniform thickness, but the present disclosure is not necessarily limited thereto. The third gate-insulating layer GI3 may include an inorganic insulating material. Examples of the inorganic insulating material that may be used as the third gate-insulating layer GI3 may include silicon oxide (SiOₓ), silicon nitride (SiNₓ), silicon oxynitride (SiOₓN_{y}), or the like. These may be used alone or in combination with each other.

The second capacitor electrode CAPE2 may be located on the third gate-insulating layer GI3. The second capacitor electrode CAPE2 may overlap the first capacitor electrode CAPE1 in a plan view. The second capacitor electrode CAPE2 may be spaced apart from the first capacitor electrode CAPE1 by the third gate-insulating layer GI3. The first capacitor electrode CAPE1 and the second capacitor electrode CAPE2 may form a second capacitor CAP2. The second capacitor electrode CAPE2 may include a conductive material, such as a metal, an alloy, a conductive metal nitride, a conductive metal oxide, a transparent conductive oxide, or the like. These may be used alone or in combination with each other.

In one or more embodiments, the first capacitor CAP1 of FIG. 4 may correspond to the first capacitor C1 of FIGS. 3A and 3B, and the second capacitor CAP2 of FIG. 4 may correspond to the second capacitor C2 of FIG. 3B. However, the present disclosure is not necessarily limited thereto. In one or more embodiments, the first capacitor CAP1 of FIG. 4 may correspond to the second capacitor C2 of FIG. 3B, and the second capacitor CAP2 of FIG. 4 may correspond to the first capacitor C1 of FIGS. 3A and 3B. Hereinafter, a case in which the first capacitor CAP1 of FIG. 4 corresponds to the first capacitor C1 of FIGS. 3A and 3B, and the second capacitor CAP2 of FIG. 4 corresponds to the second capacitor C2 of FIG. 3B is described as an example.

The inter-layer insulating layer ILD may be located on the third gate-insulating layer GI3. The inter-layer insulating layer ILD may cover the second capacitor electrode CAPE2. For example, the inter-layer insulating layer ILD may have a substantially flat upper surface without forming a step difference around the second capacitor electrode CAPE2, but the present disclosure is not necessarily limited thereto. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), or the like. These may be used alone or in combination with each other.

The source electrode SE and the drain electrode DE may be located on the inter-layer insulating layer ILD. The source electrode SE may be connected to the source area of the active pattern ACT through a contact hole penetrating the first to third gate-insulating layers GI1, GI2, and GI3 and the inter-layer insulating layer ILD. The drain electrode DE may be connected to the drain area of the active pattern ACT through a contact hole penetrating the first to third gate-insulating layers GI1, GI2, and GI3 and the inter-layer insulating layer ILD. Each of the source electrode SE and the drain electrode DE may include a conductive material, such as a metal, an alloy, a conductive metal nitride, a conductive metal oxide, a transparent conductive oxide, or the like. These may be used alone or in combination with each other.

Accordingly, the thin film transistor TR including the active pattern ACT, the gate electrode GE, the source electrode SE, and the drain electrode DE may be located on the substrate SUB.

The via-insulating layer VIA may be located on the inter-layer insulating layer ILD. The via-insulating layer VIA may cover the source electrode SE and the drain electrode DE. For example, the via-insulating layer VIA may be located to sufficiently cover the source electrode SE and the drain electrode DE with a relatively thick thickness. The via-insulating layer VIA may have a substantially flat upper surface. The via-insulating layer VIA may include an organic insulating material. Examples of the organic insulating material that may be used as the via-insulating layer VIA may include a polyacryl-based resin, a polyimide-based resin, a polyamide-based resin, a siloxane-based resin, an acryl-based resin, an epoxy-based resin, or the like. These may be used alone or in combination with each other.

The pixel electrode PE may be located on the via-insulating layer VIA. The pixel electrode PE may be connected to the source electrode SE or the drain electrode DE through a contact hole penetrating the via-insulating layer VIA. Accordingly, the pixel electrode PE may be electrically connected to the thin film transistor TR. The pixel electrode PE may include a conductive material, such as a metal, an alloy, a conductive metal nitride, a conductive metal oxide, a transparent conductive oxide, or the like. These may be used alone or in combination with each other. For example, the pixel electrode PE may function as the anode of the light-emitting element LD of FIGS. 3A and 3B.

In one or more embodiments, the display panel DP may further include a light-emitting element connection electrode and a second via-insulating layer located on the via-insulating layer VIA. In this case, the light-emitting element connection electrode may be connected to the source electrode SE or the drain electrode DE through a contact hole penetrating the via-insulating layer VIA, and the second via-insulating layer may cover the light-emitting element connection electrode on the via-insulating layer VIA. In this case, the pixel electrode PE may be connected to the light-emitting element connection electrode through a contact hole penetrating the second via-insulating layer.

The pixel-defining layer PDL may be located on the via-insulating layer VIA. The pixel-defining layer PDL may cover an edge of the pixel electrode PE, and may expose an upper surface of the pixel electrode PE. The pixel-defining layer PDL may include an organic insulating material and/or an inorganic insulating material.

The light-emitting layer EML may be located on the pixel electrode PE. The light-emitting layer EML may emit light having a corresponding color (e.g., red, green, blue, etc.). In one or more embodiments, the light-emitting layer EML may include at least one of an organic light-emitting material or a quantum dot. For example, the light-emitting layer EML may have a single-layer structure including one light-emitting structure. However, the present disclosure is not necessarily limited thereto, and the light-emitting layer EML may have a tandem structure including a plurality of light-emitting structures.

The common electrode CME may be located on the pixel-defining layer PDL and the light-emitting layer EML. The common electrode CME may cover the pixel-defining layer PDL and the light-emitting layer EML. The common electrode CME may be located along the profiles of the pixel-defining layer PDL and the light-emitting layer EML with a substantially uniform thickness. The common electrode CME may include a conductive material, such as a metal, an alloy, a conductive metal nitride, a conductive metal oxide, a transparent conductive oxide, or the like. These may be used alone or in combination with each other. For example, the common electrode CME may function as the cathode of the light-emitting element LD of FIGS. 3A and 3B.

Accordingly, the light-emitting element LD including the pixel electrode PE, the light-emitting layer EML, and the common electrode CME may be located on the via-insulating layer VIA.

The encapsulation layer TFE may be located on the common electrode CME. The encapsulation layer TFE may reduce or prevent impurities, moisture, or the like from penetrating into the light-emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), or the like. These may be used alone or in combination with each other. For example, the organic encapsulation layer may include a polymer cured material, such as polyacrylate.

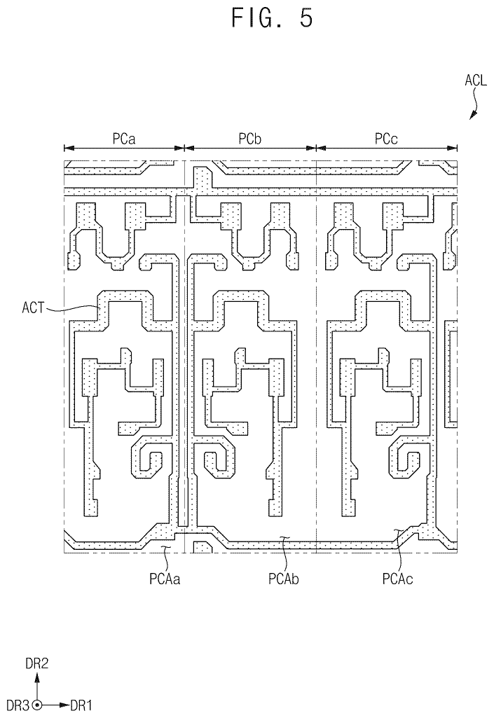

FIGS. 5, 6, 7, 8, 9, 10, 11, 12, and 13 are layout views illustrating an example of a pixel included in the display device of FIG. 1. For example, FIGS. 5 to 13 are layout views illustrating the circuit element layer PCL of FIG. 4 including the pixel-driving circuit PC′ of FIG. 3B.

Referring to FIGS. 3B, 4, and 5, the pixel PX may include the first to third sub-pixels. The first to third sub-pixels may emit light of different respective colors. For example, the first sub-pixel may emit red light, the second sub-pixel may emit green light, and the third sub-pixel may emit blue light, but the present disclosure is not necessarily limited thereto.

The first sub-pixel may include a first pixel-driving circuit PCa, and a first pixel circuit area PCAa may be defined as an area in which the first pixel-driving circuit PCa is located. The second sub-pixel may include a second pixel-driving circuit PCb, and a second pixel circuit area PCAb may be defined as an area in which the second pixel-driving circuit PCb is located. The third sub-pixel may include a third pixel-driving circuit PCc, and a third pixel circuit area PCAc may be defined as an area in which the third pixel-driving circuit PCc is located.

In FIG. 5, the first to third pixel-driving circuits PCa, PCb, and PCc are illustrated as being sequentially arranged along the first direction DR1 in a rectangular shape, but the present disclosure is not necessarily limited thereto. The shape of the first to third pixel-driving circuits PCa, PCb, and PCc and the arrangement relationship between the first to third pixel-driving circuits PCa, PCb, and PCc may be varied according to embodiments.

The first to third pixel-driving circuits PCa, PCb, and PCc may have substantially identical or symmetrical to each other. Hereinafter, the arrangement structure of transistors, capacitors, and lines included in the first pixel-driving circuit PCa will be described in more detail. The descriptions of the first pixel-driving circuit PCa may be substantially equally applied to the second pixel-driving circuit PCb and the third pixel-driving circuit PCc.

FIG. 5 is a layout view illustrating an active layer ACL.

As illustrated in FIGS. 4 and 5, the active layer ACL may be located on the substrate SUB. In one or more embodiments, the active layer ACL may include a silicon semiconductor material. Examples of the silicon semiconductor material that may be used as the active layer ACL may include amorphous silicon, polycrystalline silicon, or the like.

The active layer ACL may include the active pattern ACT. The active pattern ACT may include a channel of each of transistors included in the pixel-driving circuit PC′ of FIG. 3B.

The first gate-insulating layer GI1 may be located on the substrate SUB. The first gate-insulating layer GI1 may cover the active pattern ACT on the substrate SUB.

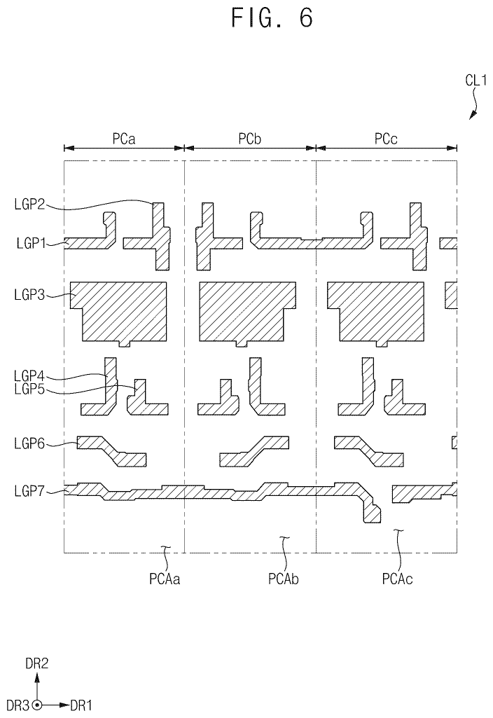

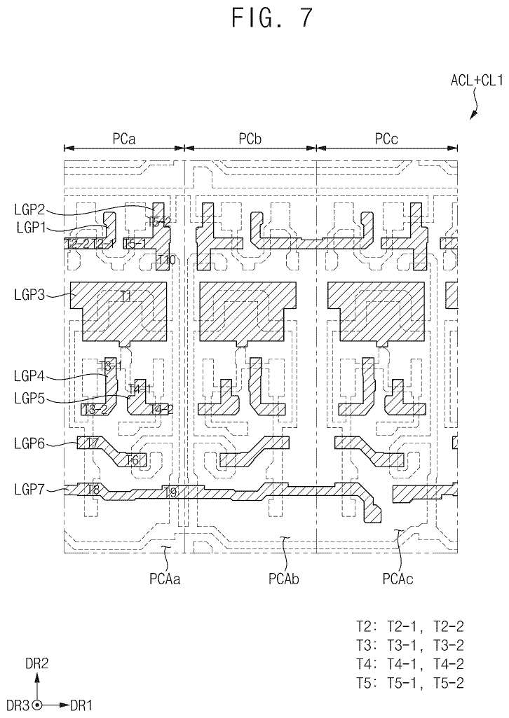

FIG. 6 is a layout view illustrating a first conductive layer CL1. FIG. 7 is a layout view in which the first conductive layer CL1 is further located on the active layer ACL.

Referring further to FIGS. 6 and 7, the first conductive layer CL1 may be located on the active layer ACL. For example, the first conductive layer CL1 may be located on the first gate-insulating layer GI1. The first conductive layer CL1 may include a conductive material, such as a metal, an alloy, a conductive metal nitride, a conductive metal oxide, a transparent conductive oxide, or the like. These may be used alone or in combination with each other. For example, the first conductive layer CL1 may be referred to as a first gate conductive layer.

The first conductive layer CL1 may include first to seventh lower gate patterns LGP1, LGP2, LGP3, LGP4, LGP5, LGP6, and LGP7. The first to seventh lower gate patterns LGP1, LGP2, LGP3, LGP4, LGP5, LGP6, and LGP7 may be spaced apart from each other in a plan view. The first to seventh lower gate patterns LGP1, LGP2, LGP3, LGP4, LGP5, LGP6, and LGP7 may be located in the same layer as the gate electrode GE of FIG. 4.

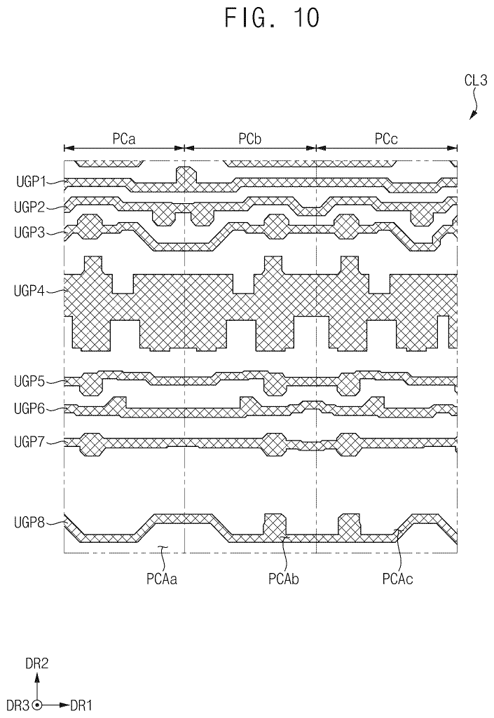

The first lower gate pattern LGP1 may overlap the active pattern ACT in a plan view. A portion of the first lower gate pattern LGP1 overlapping the active pattern ACT may form the second transistor T2. For example, the second transistor T2 may include the (2-1)-th transistor T2-1 and the (2-2)-th transistor T2-2 that are connected in series. A first portion of the first lower gate pattern LGP1 overlapping the active pattern ACT may be the gate electrode of the (2-1)-th transistor T2-1. A second portion of the first lower gate pattern LGP1 overlapping the active pattern ACT may be the gate electrode of the (2-2)-th transistor T2-2. The first lower gate pattern LGP1 may receive the first gate signal GW. For example, the first lower gate pattern LGP1 may receive the first gate signal GW from a third upper gate pattern UGP3 of FIG. 10.

The second lower gate pattern LGP2 may overlap the active pattern ACT in a plan view. A portion of the second lower gate pattern LGP2 overlapping the active pattern ACT may form the fifth transistor T5 and the tenth transistor T10. For example, the fifth transistor T5 may include the (5-1)-th transistor T5-1 and the (5-2)-th transistor T5-2 that are connected in series. A first portion of the second lower gate pattern LGP2 overlapping the active pattern ACT may be the gate electrode of the (5-1)-th transistor T5-1. A second portion of the second lower gate pattern LGP2 overlapping the active pattern ACT may be the gate electrode of the (5-2)-th transistor T5-2. A third portion of the second lower gate pattern LGP2 overlapping the active pattern ACT may be the gate electrode of the tenth transistor T10. The second lower gate pattern LGP2 may receive the second gate signal GC. For example, the second lower gate pattern LGP2 may receive the second gate signal GC from a second upper gate pattern UGP2 of FIG. 10.

The third lower gate pattern LGP3 may overlap the active pattern ACT in a plan view. A portion of the third lower gate pattern LGP3 overlapping the active pattern ACT may form the first transistor T1. The portion of the third lower gate pattern LGP3 overlapping the active pattern ACT may be the gate electrode of the first transistor T1.

The fourth lower gate pattern LGP4 may overlap the active pattern ACT in a plan view. A portion of the fourth lower gate pattern LGP4 overlapping the active pattern ACT may form the third transistor T3. For example, the third transistor T3 may include the (3-1)-th transistor T3-1 and the (3-2)-th transistor T3-2 that are connected in series. A first portion of the fourth lower gate pattern LGP4 overlapping the active pattern ACT may be the gate electrode of the (3-1)-th transistor T3-1. A second portion of the fourth lower gate pattern LGP4 overlapping the active pattern ACT may be the gate electrode of the (3-2)-th transistor T3-2. The fourth lower gate pattern LGP4 may receive the second gate signal GC. For example, the fourth lower gate pattern LGP4 may receive the second gate signal GC from a fifth upper gate pattern UGP5 of FIG. 10.

The fifth lower gate pattern LGP5 may overlap the active pattern ACT in a plan view. A portion of the fifth lower gate pattern LGP5 overlapping the active pattern ACT may form the fourth transistor T4. For example, the fourth transistor T4 may include the (4-1)-th transistor T4-1 and the (4-2)-th transistor T4-2 that are connected in series. A first portion of the fifth lower gate pattern LGP5 overlapping the active pattern ACT may be the gate electrode of the (4-1)-th transistor T4-1. A second portion of the fifth lower gate pattern LGP5 overlapping the active pattern ACT may be the gate electrode of the (4-2)-th transistor T4-2. The fifth lower gate pattern LGP5 may receive the third gate signal GI. For example, the fifth lower gate pattern LGP5 may receive the third gate signal GI from a sixth upper gate pattern UGP6 of FIG. 10.

The sixth lower gate pattern LGP6 may overlap the active pattern ACT in a plan view. A portion of the sixth lower gate pattern LGP6 overlapping the active pattern ACT may form the sixth transistor T6 and the seventh transistor T7. A first portion of the sixth lower gate pattern LGP6 overlapping the active pattern ACT may be the gate electrode of the sixth transistor T6. A second portion of the sixth lower gate pattern LGP6 overlapping the active pattern ACT may be the gate electrode of the seventh transistor T7. The sixth lower gate pattern LGP6 may receive the emission control signal EM. For example, the sixth lower gate pattern LGP6 may receive the emission control signal EM from a seventh upper gate pattern UGP7 of FIG. 10.

The seventh lower gate pattern LGP7 may overlap the active pattern ACT in a plan view. A portion of the seventh lower gate pattern LGP7 overlapping the active pattern ACT may form the eighth transistor T8 and the ninth transistor T9. A first portion of the seventh lower gate pattern LGP7 overlapping the active pattern ACT may be the gate electrode of the eighth transistor T8. A second portion of the seventh lower gate pattern LGP7 overlapping the active pattern ACT may be the gate electrode of the ninth transistor T9. The fourth gate signal GB may be applied to the seventh lower gate pattern LGP7.

The second gate-insulating layer GI2 may be located on the first gate-insulating layer GI1. The second gate-insulating layer GI2 may cover the first to seventh lower gate patterns LGP1, LGP2, LGP3, LGP4, LGP5, LGP6, and LGP7 on the first gate-insulating layer GI1.

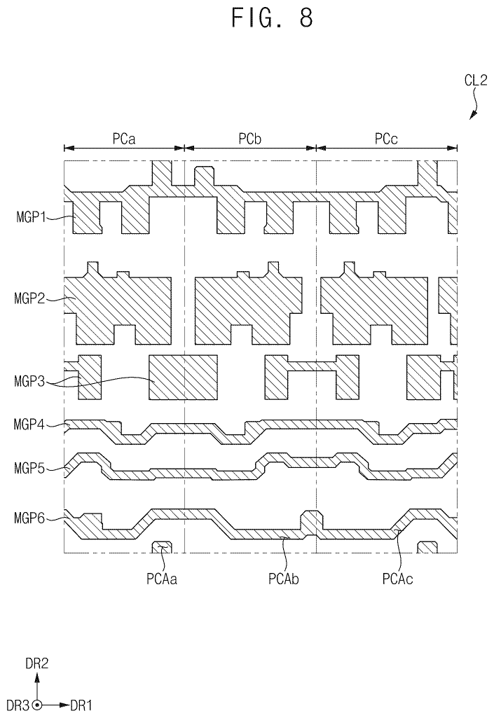

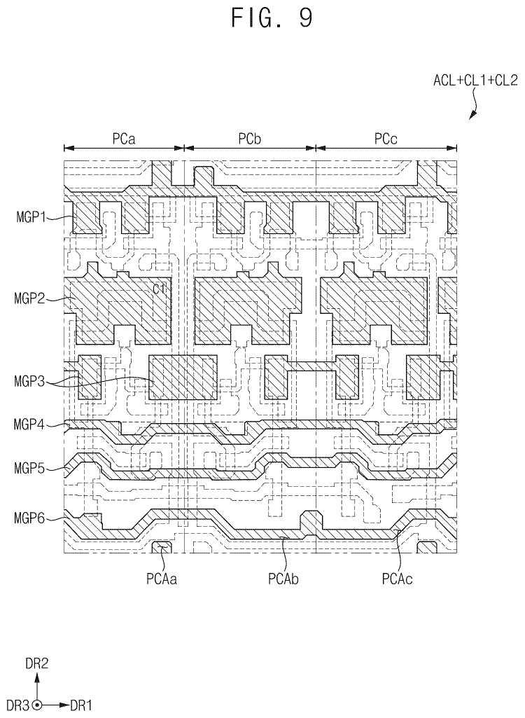

FIG. 8 is a layout view illustrating a second conductive layer CL2. FIG. 9 is a layout view in which the second conductive layer CL2 is further located on the first conductive layer CL1.

Referring further to FIGS. 8 and 9, the second conductive layer CL2 may be located on the first conductive layer CL1. For example, the second conductive layer CL2 may be located on the second gate-insulating layer GI2. The second conductive layer CL2 may include a conductive material, such as a metal, an alloy, a conductive metal nitride, a conductive metal oxide, a transparent conductive oxide, or the like. These may be used alone or in combination with each other. For example, the second conductive layer CL2 may be referred to as a second gate conductive layer.

The second conductive layer CL2 may include first to six middle gate patterns MGP1, MGP2, MGP3, MGP4, MGP5, and MGP6. The first to six middle gate patterns MGP1, MGP2, MGP3, MGP4, MGP5, and MGP6 may be spaced apart from each other in a plan view. The first to six middle gate patterns MGP1, MGP2, MGP3, MGP4, MGP5, and MGP6 may be located in the same layer as the first capacitor electrode CAPE1 of FIG. 4.

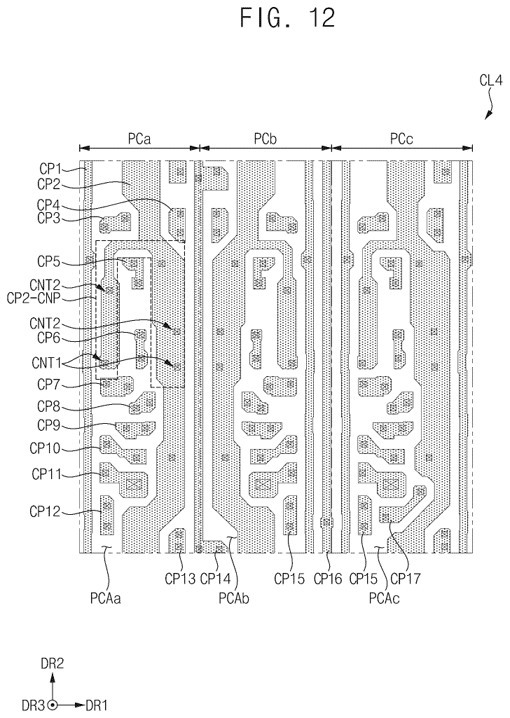

The first middle gate pattern MGP1 may extend in the first direction DR1. The bias voltage VOBS may be applied to the first middle gate pattern MGP1. The first middle gate pattern MGP1 may be electrically connected to the active pattern ACT through a connection pattern (e.g., a thirteenth connection pattern CP13 of FIG. 12). Accordingly, the first middle gate pattern MGP1 may provide the bias voltage VOBS to the ninth transistor T9. For example, the first middle gate pattern MGP1 may be referred to as a bias voltage line.

The second middle gate pattern MGP2 may overlap the third lower gate pattern LGP3 in a plan view. The second middle gate pattern MGP2 may be spaced apart from the third lower gate pattern LGP3 by the second gate-insulating layer GI2. The third lower gate pattern LGP3 and the second middle gate pattern MGP2 may form the first capacitor C1. In one or more embodiments, the second middle gate pattern MGP2 may be referred to as a capacitor pattern.

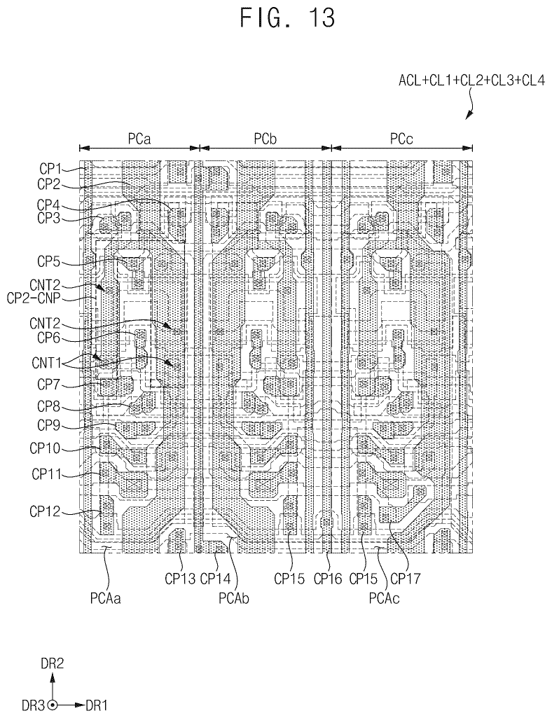

The third middle gate pattern MGP3 may receive the driving voltage ELVDD. In one or more embodiments, the third middle gate pattern MGP3 may be connected to a second connection pattern CP2 of FIG. 12 through a first contact hole (CNT1, see FIG. 13), and may receive the driving voltage ELVDD from the second connection pattern CP2. For example, the third middle gate pattern MGP3 may be referred to as a first driving voltage transmission pattern.

In one or more embodiments, the third middle gate pattern MGP3 may be provided in a plural, and the plurality of third middle gate patterns MGP3 may be spaced apart from each other in the first direction DR1. However, the present disclosure is not necessarily limited thereto.

In one or more embodiments, the third middle gate pattern MGP3 may form a first voltage transmission path that transmits the driving voltage ELVDD in the first direction DR1. A detailed description thereof will be described below with reference to FIGS. 12, 13, and 14.

The fourth middle gate pattern MGP4 may extend in the first direction DR1. The first initialization voltage VINT may be applied to the fourth middle gate pattern MGP4. The fourth middle gate pattern MGP4 may be electrically connected to the active pattern ACT through a connection pattern (e.g., a ninth connection pattern CP9 of FIG. 12). Accordingly, the fourth middle gate pattern MGP4 may provide the first initialization voltage VINT to the fourth transistor T4 (for example, the (4-2)-th transistor T4-2). For example, the fourth middle gate pattern MGP4 may be referred to as a gate initialization voltage line.

The fifth middle gate pattern MGP5 may extend in the first direction DR1. The fifth middle gate pattern MGP5 may increase the yield of a display device. For example, when a defect occurs in some of lines during a process of manufacturing a display device, the fifth middle gate pattern MGP5 may replace some of the lines. For example, the fifth middle gate pattern MGP5 may be referred to as a repair line.

The sixth middle gate pattern MGP6 may extend in the first direction DR1. The second initialization voltage VAINT may be applied to the sixth middle gate pattern MGP6. The sixth middle gate pattern MGP6 may be electrically connected to the active pattern ACT through a connection pattern (e.g., a twelfth connection pattern CP12 of FIG. 12). Accordingly, the sixth middle gate pattern MGP6 may provide the second initialization voltage VAINT to the eighth transistor T8. In one or more embodiments, the sixth middle gate pattern MGP6 may provide the second initialization voltage VAINT to the eighth transistor T8 included in the first pixel-driving circuit PCa. For example, the sixth middle gate pattern MGP6 may be referred to as an anode initialization voltage line.

The third gate-insulating layer GI3 may be located on the second gate-insulating layer GI2. The third gate-insulating layer GI3 may cover the first to six middle gate patterns MGP1, MGP2, MGP3, MGP4, MGP5, and MGP6 on the second gate-insulating layer GI2.

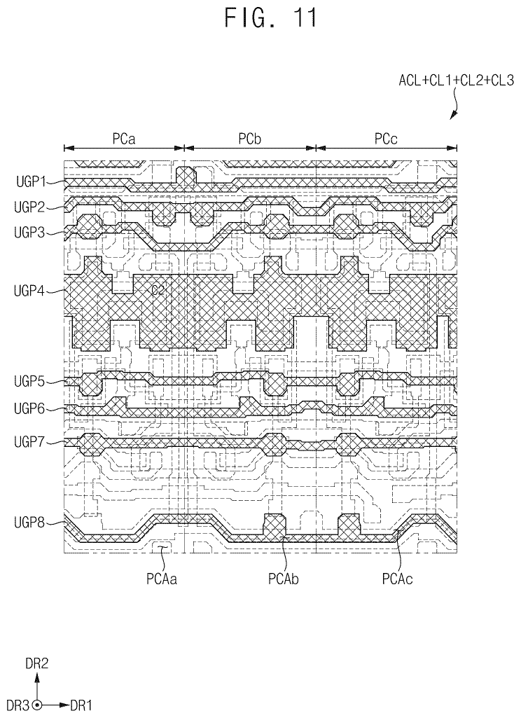

FIG. 10 is a layout view illustrating a third conductive layer CL3. FIG. 11 is a layout view in which the third conductive layer CL3 is further located on the second conductive layer CL2.

Referring further to FIGS. 10 and 11, the third conductive layer CL3 may be located on the second conductive layer CL2. For example, the third conductive layer CL3 may be located on the third gate-insulating layer GI3. The third conductive layer CL3 may include a conductive material, such as a metal, an alloy, a conductive metal nitride, a conductive metal oxide, a transparent conductive oxide, or the like. These may be used alone or in combination with each other. The third conductive layer CL3 may be referred to as a third gate conductive layer.

The third conductive layer CL3 may include first to eighth upper gate patterns UGP1, UGP2, UGP3, UGP4, UGP5, UGP6, UGP7, and UGP8. The first to eighth upper gate patterns UGP1, UGP2, UGP3, UGP4, UGP5, UGP6, UGP7, and UGP8 may be spaced apart from each other in a plan view. The first to eighth upper gate patterns UGP1, UGP2, UGP3, UGP4, UGP5, UGP6, UGP7, and UGP8 may be located in the same layer as the second capacitor electrode CAPE2 of FIG. 4.

The first upper gate pattern UGP1 may extend in the first direction DR1. The reference voltage VREF may be applied to the first upper gate pattern UGP1. The first upper gate pattern UGP1 may be electrically connected to the active pattern ACT through a connection pattern (e.g., a fourteenth connection pattern CP14 of FIG. 12). Accordingly, the first upper gate pattern UGP1 may provide the reference voltage VREF to the fifth transistor T5 (for example, the (5-2)-th transistor T5-2). For example, the first upper gate pattern UGP1 may be referred to as a reference voltage line.

The second upper gate pattern UGP2 may extend in the first direction DR1. The second gate signal SC may be applied to the second upper gate pattern UGP2. The second upper gate pattern UGP2 may be electrically connected to the second lower gate pattern LGP2 through a connection pattern (e.g., a fourth connection pattern CP4 of FIG. 12). Accordingly, the second upper gate pattern UGP2 may provide the second gate signal GC to the gate electrode of the (5-1)-th transistor T5-1, the gate electrode of the (5-2)-th transistor T5-2, and to the gate electrode of the tenth transistor T10. For example, the second upper gate pattern UGP2 may be referred to as a second gate line.

The third upper gate pattern UGP3 may extend in the first direction DR1. The first gate signal GW may be applied to the third upper gate pattern UGP3. The third upper gate pattern UGP3 may be electrically connected to the first lower gate pattern LGP1 through a connection pattern (e.g., a third connection pattern CP3 of FIG. 12). Accordingly, the third upper gate pattern UGP3 may provide the first gate signal GW to the gate electrode of the (2-1)-th transistor T2-1 and to the gate electrode of the (2-2)-th transistor T2-2. For example, the third upper gate pattern UGP3 may be referred to as a first gate line.

The fourth upper gate pattern UGP4 may be located on the third middle gate pattern MGP3. The fourth upper gate pattern UGP4 may extend in the first direction DR1. The fourth upper gate pattern UGP4 may receive the driving voltage ELVDD. In one or more embodiments, the fourth upper gate pattern UGP4 may be connected to a second connection pattern CP2 of FIG. 12 through a second contact hole (e.g., second contact hole CNT2 in FIG. 13), and may receive the driving voltage ELVDD from the second connection pattern CP2. For example, the fourth upper gate pattern UGP4 may be referred to as a second driving voltage transmission pattern.

In one or more embodiments, as illustrated in FIGS. 9 and 11, the third middle gate pattern MGP3 and the fourth upper gate pattern UGP4 may be spaced apart from each other in a plan view. However, the present disclosure is not necessarily limited thereto.

In one or more embodiments, the fourth upper gate pattern UGP4 may form a second voltage transmission path that transmits the driving voltage ELVDD in the first direction DR1. A detailed description thereof will be described below with reference to FIGS. 12, 13, and 14.

In one or more embodiments, the fourth upper gate pattern UGP4 may overlap the second middle gate pattern MGP2 in a plan view. As described above, the second middle gate pattern MGP2 may be referred to as the capacitor pattern. The fourth upper gate pattern UGP4 may be spaced apart from the second middle gate pattern MGP2 by the third gate-insulating layer GI3. A portion of the fourth upper gate pattern UGP4 overlapping the second middle gate pattern MGP2 in a plan view may form the second capacitor C2.

The fifth upper gate pattern UGP5 may extend in the first direction DR1. The second gate signal GC may be applied to the fifth upper gate pattern UGP5. The fifth upper gate pattern UGP5 may be electrically connected to the fourth lower gate pattern LGP4 through a connection pattern (e.g., a seventh connection pattern CP7 of FIG. 12). Accordingly, the fifth upper gate pattern UGP5 may provide the second gate signal GC to the gate electrode of the (3-1)-th transistor T3-1 and to the gate electrode of the (3-2)-th transistor T3-2. For example, the fifth upper gate pattern UGP5 may be referred to as the second gate line.

The sixth upper gate pattern UGP6 may extend in the first direction DR1. The third gate signal GI may be applied to the sixth upper gate pattern UGP6. The sixth upper gate pattern UGP6 may be electrically connected to the fifth lower gate pattern LGP5 through a connection pattern (e.g., an eighth connection pattern CP8 of FIG. 12). Accordingly, the sixth upper gate pattern UGP6 may provide the third gate signal GI to the gate electrode of the (4-1)-th transistor T4-1 and to the gate electrode of the (4-2)-th transistor T4-2. For example, the sixth upper gate pattern UGP6 may be referred to as a third gate line.

The seventh upper gate pattern UGP7 may extend in the first direction DR1. The emission control signal EM may be applied to the seventh upper gate pattern UGP7. The seventh upper gate pattern UGP7 may be electrically connected to the sixth lower gate pattern LGP6 through a connection pattern (e.g., a tenth connection pattern CP10 of FIG. 12). Accordingly, the seventh upper gate pattern UGP7 may provide the emission control signal EM to the gate electrode of the sixth transistor T6 and the gate electrode of the seventh transistor T7. For example, the seventh upper gate pattern UGP7 may be referred to as an emission line.

The eighth upper gate pattern UGP8 may extend in the first direction DR1. The second initialization voltage VAINT may be applied to the eighth upper gate pattern UGP8. The eighth upper gate pattern UGP8 may be electrically connected to the active pattern ACT through a connection pattern (e.g., a fifteenth connection pattern CP15 of FIG. 12). Accordingly, the eighth upper gate pattern UGP8 may provide the second initialization voltage VAINT to the eighth transistor T8. In one or more embodiments, the eighth upper gate pattern UGP8 may provide the second initialization voltage VAINT to the eighth transistor T8 included in the second pixel-driving circuit PCb and the eighth transistor T8 included in the third pixel-driving circuit PCc. For example, the eighth upper gate pattern UGP8 may be referred to as an anode initialization voltage line.

The inter-layer insulating layer ILD may be located on the third gate-insulating layer GI3. The inter-layer insulating layer ILD may cover the first to eighth upper gate patterns UGP1, UGP2, UGP3, UGP4, UGP5, UGP6, UGP7, and UGP8 on the third gate-insulating layer GI3.

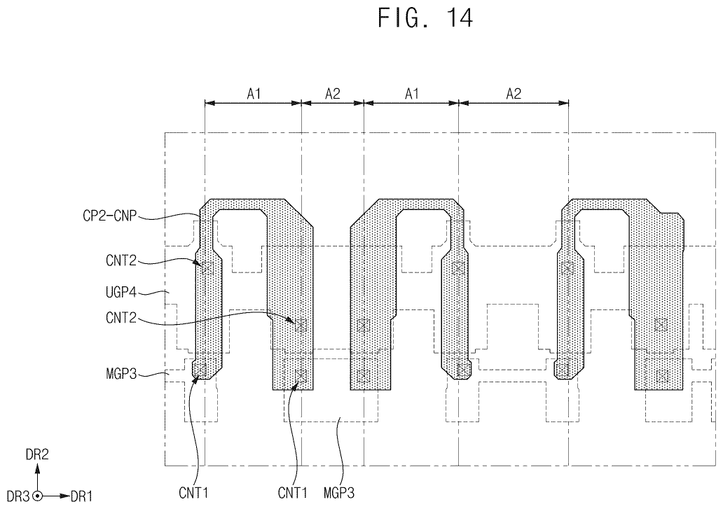

FIG. 12 is a layout view illustrating a fourth conductive layer CL4. FIG. 13 is a layout view in which the fourth conductive layer CL4 is further located on the third conductive layer CL3. FIG. 14 is a layout view for describing a path through which a driving voltage is transmitted in a first direction.

Referring further to FIGS. 12 and 13, the fourth conductive layer CL4 may be located on the third conductive layer CL3. For example, the fourth conductive layer CL4 may be located on the inter-layer insulating layer ILD. The fourth conductive layer CL4 may include a conductive material, such as a metal, an alloy, a conductive metal nitride, a conductive metal oxide, a transparent conductive oxide, or the like. These may be used alone or in combination with each other. The fourth conductive layer CL4 may be referred to as a source-drain conductive layer.

The fourth conductive layer CL4 may include first to seventeenth connection patterns CP1, CP2, CP3, CP4, CP5, CP6, CP7, CP8, CP9, CP10, CP11, CP12, CP13, CP14, CP15, CP16, and CP17. The first to seventeenth connection patterns CP1, CP2, CP3, CP4, CP5, CP6, CP7, CP8, CP9, CP10, CP11, CP12, CP13, CP14, CP15, CP16, and CP17 may be spaced apart from each other in a plan view. The first to seventeenth connection patterns CP1, CP2, CP3, CP4, CP5, CP6, CP7, CP8, CP9, CP10, CP11, CP12, CP13, CP14, CP15, CP16, and CP17 may be located in the same layer as the source electrode SE and drain electrode DE of FIG. 4.

The first connection pattern CP1 may extend in the second direction DR2. The data voltage VDATA may be applied to the first connection pattern CP1. The first connection pattern CP1 may be connected to the active pattern ACT through a contact hole. Accordingly, the first connection pattern CP1 may provide the data voltage VDATA to the second transistor T2 (for example, the (2-2)-th transistor T2-2). For example, the first connection pattern CP1 may be referred to as a data line.

The second connection pattern CP2 may be located on the fourth upper gate pattern UGP4. The second connection pattern CP2 may extend in the second direction DR2. The driving voltage ELVDD may be applied to the second connection pattern CP2. For example, the second connection pattern CP2 may be referred to as a driving voltage line.

Referring further to FIG. 14, the second connection pattern CP2 may include a connection portion CP2-CNP. In one or more embodiments, the connection portion CP2-CNP may include a first extension portion extending in the first direction DR1, and a second extension portion extending in the second direction DR2. For example, the connection portion CP2-CNP may have a substantial U-shape (e.g., upside-down U-shape) in a plan view, but the present disclosure is not limited thereto.

The connection portion CP2-CNP of the second connection pattern CP2 may be connected to the third middle gate pattern MGP3 through a first contact hole CNT1, and may be connected to the fourth upper gate pattern UGP4 through a second contact hole CNT2 different from the first contact hole CNT1. In one or more embodiments, the second extension portion that extends in the second direction DR2 of the connection portion CP2-CNP may be connected to the third middle gate pattern MGP3 and the fourth upper gate pattern UGP4 through the first contact hole CNT1 and the second contact hole CNT2, respectively. Accordingly, the second connection pattern CP2 may provide the driving voltage ELVDD to the third middle gate pattern MGP3 and to the fourth upper gate pattern UGP4.

The second connection pattern CP2 may overlap the third middle gate pattern MGP3 and the fourth upper gate pattern UGP4 in a plan view. In one or more embodiments, a first overlap area between the third middle gate pattern MGP3 and the second connection pattern CP2 may be less than, or smaller than, a second overlap area between the fourth upper gate pattern UGP4 and the second connection pattern CP2. The first overlap area may be defined as an area where the third middle gate pattern MGP3 and the second connection pattern CP2 overlap each other in a plan view. The second overlap area may be defined as an area where the fourth upper gate pattern UGP4 and the second connection pattern CP2 overlap each other in a plan view. However, the present disclosure is not necessarily limited thereto.

The second connection pattern CP2 may be provided in a plural, and the plurality of second connection patterns CP2 may be spaced apart from each other in the first direction DR1. In one or more embodiments, the third middle gate pattern MGP3 may connect adjacent second connection patterns CP2.

The third middle gate pattern MGP3 may form the first voltage transmission path that transmits the driving voltage ELVDD in the first direction DR1, and the fourth upper gate pattern UGP4 may form the second voltage transmission path that transmits the driving voltage ELVDD in the first direction DR1. The first voltage transmission path and the second voltage transmission path may be different paths.

For example, a first area A1 and a second area A2 adjacent to each other in the first direction DR1 may be defined. The first area A1 and the second area A2 may be alternately arranged along the first direction DR1. In the first area A1, the driving voltage ELVDD may be transmitted in the first direction DR1 through the connection portion CP2-CNP of the second connection pattern CP2 or the fourth upper gate pattern UGP4. In the second area A2, the driving voltage ELVDD may be transmitted in the first direction DR1 through the third middle gate pattern MGP3 or the fourth upper gate pattern UGP4.

The third connection pattern CP3 may overlap the first lower gate pattern LGP1 and the third upper gate pattern UGP3 in a plan view. The third connection pattern CP3 may be connected to the first lower gate pattern LGP1 and to the third upper gate pattern UGP3 through respective contact holes. Accordingly, the third connection pattern CP3 may electrically connect the first lower gate pattern LGP1 and the third upper gate pattern UGP3, and the third upper gate pattern UGP3 may provide the first gate signal GW to the first lower gate pattern LGP1 through the third connection pattern CP3.

The fourth connection pattern CP4 may overlap the second lower gate pattern LGP2 and the second upper gate pattern UGP2 in a plan view. The fourth connection pattern CP4 may be connected to the second lower gate pattern LGP2 and to the second upper gate pattern UGP2 through respective contact holes. Accordingly, the fourth connection pattern CP4 may electrically connect the second lower gate pattern LGP2 and the second upper gate pattern UGP2, and the second upper gate pattern UGP2 may provide the second gate signal GC to the second lower gate pattern LGP2 through the fourth connection pattern CP4.

The fifth connection pattern CP5 may overlap the active pattern ACT and the second middle gate pattern MGP2 in a plan view. The fifth connection pattern CP5 may be connected to the active pattern ACT and to the second middle gate pattern MGP2 through respective contact holes. Accordingly, the fifth connection pattern CP5 may electrically connect the active pattern ACT and the second middle gate pattern MGP2.

The sixth connection pattern CP6 may overlap the active pattern ACT and the third lower gate pattern LGP3 in a plan view. The sixth connection pattern CP6 may be connected to the active pattern ACT and to the third lower gate pattern LGP3 through respective contact holes. Accordingly, the sixth connection pattern CP6 may electrically connect the active pattern ACT and the third lower gate pattern LGP3.

The seventh connection pattern CP7 may overlap the fourth lower gate pattern LGP4 and the fifth upper gate pattern UGP5 in a plan view. The seventh connection pattern CP7 may be connected to the fourth lower gate pattern LGP4 and to the fifth upper gate pattern UGP5 through respective contact holes. Accordingly, the seventh connection pattern CP7 may electrically connect the fourth lower gate pattern LGP4 and the fifth upper gate pattern UGP5, and the fifth upper gate pattern UGP5 may provide the second gate signal GC to the fourth lower gate pattern LGP4 through the seventh connection pattern CP7.

The eighth connection pattern CP8 may overlap the fifth lower gate pattern LGP5 and the sixth upper gate pattern UGP6 in a plan view. The eighth connection pattern CP8 may be connected to the fifth lower gate pattern LGP5 and to the sixth upper gate pattern UGP6 through respective contact holes. Accordingly, the eighth connection pattern CP8 may electrically connect the fifth lower gate pattern LGP5 and the sixth upper gate pattern UGP6, and the sixth upper gate pattern UGP6 may provide the third gate signal GI to the fifth lower gate pattern LGP5 through the eighth connection pattern CP8.

The ninth connection pattern CP9 may overlap the active pattern ACT and the fourth middle gate pattern MGP4 in a plan view. The ninth connection pattern CP9 may be connected to the active pattern ACT and to the fourth middle gate pattern MGP4 through respective contact holes. Accordingly, the ninth connection pattern CP9 may electrically connect the active pattern ACT and the fourth middle gate pattern MGP4, and the fourth middle gate pattern MGP4 may provide the first initialization voltage VINT to the fourth transistor T4 through the ninth connection pattern CP9.

The tenth connection pattern CP10 may overlap the sixth lower gate pattern LGP6 and the seventh upper gate pattern UGP7 in a plan view. The tenth connection pattern CP10 may be connected to the sixth lower gate pattern LGP6 and to the seventh upper gate pattern UGP7 through respective contact holes. Accordingly, the tenth connection pattern CP10 may electrically connect the sixth lower gate pattern LGP6 and the seventh upper gate pattern UGP7, and the seventh upper gate pattern UGP7 may provide the emission control signal EM to the sixth lower gate pattern LGP6 through the tenth connection pattern CP10.

The eleventh connection pattern CP11 may overlap the active pattern ACT in a plan view. The eleventh connection pattern CP11 may be connected to the active pattern ACT and to the pixel electrode PE of FIG. 4 through respective contact holes. Accordingly, the eleventh connection pattern CP11 may electrically connect the seventh transistor T7 and the light-emitting element LD.

The twelfth connection pattern CP12 may overlap the active pattern ACT and the sixth middle gate pattern MGP6 in a plan view. The twelfth connection pattern CP12 may be connected to the active pattern ACT and to the sixth middle gate pattern MGP6 through respective contact holes. Accordingly, the twelfth connection pattern CP12 may electrically connect the active pattern ACT and the sixth middle gate pattern MGP6, and the sixth middle gate pattern MGP6 may provide the second initialization voltage VAINT to the eighth transistor T8 through the twelfth connection pattern CP12. In one or more embodiments, the twelfth connection pattern CP12 may electrically connect the eighth transistor T8 included in the first pixel-driving circuit PCa and the sixth middle gate pattern MGP6.

The thirteenth connection pattern CP13 may overlap the active pattern ACT and the first middle gate pattern MGP1 in a plan view. The thirteenth connection pattern CP13 may be connected to the active pattern ACT and to the first middle gate pattern MGP1 through respective contact holes. Accordingly, the thirteenth connection pattern CP13 may electrically connect the active pattern ACT and the first middle gate pattern MGP1, and the first middle gate pattern MGP1 may provide the bias voltage VOBS to the ninth transistor T9 through the thirteenth connection pattern CP13.

The fourteenth connection pattern CP14 may extend in the second direction DR2. The fourteenth connection pattern CP14 may overlap the active pattern ACT and the first upper gate pattern UGP1 in a plan view. The fourteenth connection pattern CP14 may be connected to the active pattern ACT and to the first upper gate pattern UGP1 through respective contact holes. Accordingly, the fourteenth connection pattern CP14 may electrically connect the active pattern ACT and the first upper gate pattern UGP1. In addition, the fourteenth connection pattern CP14 may provide the reference voltage VREF to the fifth transistor T5. For example, the fourteenth connection pattern CP14 may be referred to as a reference voltage line.

The fifteenth connection pattern CP15 may overlap the active pattern ACT and the eighth upper gate pattern UGP8 in a plan view. The fifteenth connection pattern CP15 may be connected to the active pattern ACT and to the eighth upper gate pattern UGP8 through respective contact holes. Accordingly, the fifteenth connection pattern CP15 may electrically connect the active pattern ACT and the eighth upper gate pattern UGP8, and the eighth upper gate pattern UGP8 may provide the second initialization voltage VAINT to the eighth transistor T8 through the fifteenth connection pattern CP15. In one or more embodiments, the fifteenth connection pattern CP15 may electrically connect the eighth transistor T8 included in the second pixel-driving circuit PCb and the eighth upper gate pattern UGP8, and may electrically connect the eighth transistor T8 included in the third pixel-driving circuit PCc and the eighth upper gate pattern UGP8.

The sixteenth connection pattern CP16 may extend in the second direction DR2. The sixteenth connection pattern CP16 may overlap the sixth middle gate pattern MGP6 in a plan view. The sixteenth connection pattern CP16 may be connected to the sixth middle gate pattern MGP6 through a contact hole. Accordingly, the sixteenth connection pattern CP16 may provide the second initialization voltage VAINT to the sixth middle gate pattern MGP6. For example, the sixteenth connection pattern CP16 may be referred to as an anode initialization voltage line.

The seventeenth connection pattern CP17 may overlap the seventh lower gate pattern LGP7 in a plan view. The seventeenth connection pattern CP17 may be connected to the seventh lower gate pattern LGP7 through a contact hole. The seventeenth connection pattern CP17 may electrically connect the seventh lower gate pattern LGP7 included in the first to third pixel-driving circuits PCa, PCb, and PCc positioned in an N-th column and the seventh lower gate pattern LGP7 included in the first to third pixel-driving circuits PCa, PCb, and PCc positioned in a (N+1)-th column.

According to embodiments of the present disclosure, to transmit the driving voltage ELVDD in the first direction DR1 (e.g., a horizontal direction), the display device (DD, see FIG. 1) may include a plurality of transmission patterns that are located in different layers and that receive the driving voltage ELVDD. For example, the display device may include the third middle gate pattern MGP3, the fourth upper gate pattern UGP4 located on the third middle gate pattern MGP3, and the second connection pattern CP2 located on the fourth upper gate pattern UGP4. Each of the third middle gate pattern MGP3, the fourth upper gate pattern UGP4, and the second connection pattern CP2 may transmit the driving voltage ELVDD in the first direction DR1. In other words, the driving voltage ELVDD may be transmitted in the first direction DR1 through a plurality of voltage transmission paths. Accordingly, compared to a case where the driving voltage ELVDD is transmitted in the first direction DR1 through a single voltage transmission path, a resistance occurring in the transmission patterns (or lines) transmitting the driving voltage ELVDD may be effectively reduced. As a result, a luminance difference between the pixels caused by the resistance may be reduced, a defect in which a stain is recognized in the display device may be reduced or prevented, and the display quality of the display device may be improved.

FIG. 15 is a block diagram illustrating an electronic device according to one or more embodiments of the present disclosure.

Referring to FIG. 15, an electronic device 10 according to one or more embodiments may include a display module 11, a processor 12, a memory 13, and a power module 14. The display device according to one or more embodiments may be applied to a variety of electronic devices. The electronic device 10 according to one or more embodiments may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), or a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

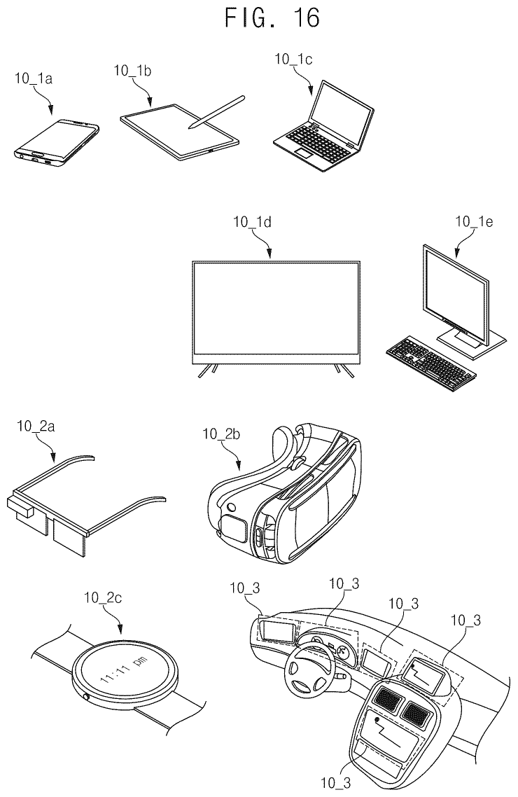

FIG. 16 is a schematic view of an electronic device according to various embodiments.

Referring to FIG. 16, various electronic devices to which a display device according to the embodiments is applied may include image display electronic devices, such as a smartphones 10_1a, a tablet PC 10_1b, a laptop 10_1c, a television 10_1d, a desk monitor 10_1e, or the like, wearable electronic devices including display modules, such as a smart glasses 10_2a, a head-mounted display 10_2b, and a smart watch 10_2c, or the like, and vehicle electronic devices 10_3 including display modules, such as a CID (center information display), which may be located on an instrument panel, a center fascia, and a dashboard of an automobile and a room mirror display, or the like.

The present disclosure may be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims, with functional equivalents thereof to be included therein.

What is claimed is:

1. A display device comprising:
a substrate;
a first driving voltage transmission pattern above the substrate and configured to receive a driving voltage;
a second driving voltage transmission pattern above the first driving voltage transmission pattern, extending in a first direction, and configured to receive the driving voltage;
a driving voltage line above the second driving voltage transmission pattern, extending in a second direction crossing the first direction, and comprising a connection portion connected to the first driving voltage transmission pattern through a first contact hole and connected to the second driving voltage transmission pattern through a second contact hole; and
a light-emitting element above the driving voltage line.

2. The display device of claim 1, wherein the connection portion of the driving voltage line comprises a first extension portion extending in the first direction and a second extension portion extending in the second direction.

3. The display device of claim 2, wherein the second extension portion is connected to the first driving voltage transmission pattern and to the second driving voltage transmission pattern through the first contact hole and through the second contact hole, respectively.

4. The display device of claim 2, wherein the connection portion of the driving voltage line is substantially U-shaped in a plan view.

5. The display device of claim 1, wherein the first driving voltage transmission pattern and the second driving voltage transmission pattern are spaced apart from each other in a plan view.

6. The display device of claim 1, wherein the driving voltage line is provided as a plurality of driving voltage lines spaced apart in the first direction.

7. The display device of claim 6, wherein the first driving voltage transmission pattern connects adjacent ones of the driving voltage lines.

8. The display device of claim 1, wherein the first driving voltage transmission pattern is provided as a plurality of first driving voltage transmission patterns spaced apart from each other in the first direction.

9. The display device of claim 1, further comprising a capacitor pattern at a same layer as the first driving voltage transmission pattern, spaced apart from the first driving voltage transmission pattern in a plan view, and having capacitance with a portion of the second driving voltage transmission pattern overlapping the capacitor pattern.

10. The display device of claim 1, further comprising:
an active pattern above the substrate;
a gate electrode above the active pattern;
a first capacitor electrode above the gate electrode;
a second capacitor electrode above the first capacitor electrode; and
a source electrode at a layer above the second capacitor electrode.

11. The display device of claim 10, wherein the first driving voltage transmission pattern is at a same layer as the first capacitor electrode, and
wherein the second driving voltage transmission pattern is at a same layer as the second capacitor electrode.

12. The display device of claim 11, wherein the driving voltage line is at a same layer as the source electrode.

13. The display device of claim 12, wherein a first overlap area between the first driving voltage transmission pattern and the driving voltage line is less than a second overlap area between the second driving voltage transmission pattern and the driving voltage line.

14. A display device comprising:
a substrate;
a first driving voltage transmission pattern above the substrate, configured to receive a driving voltage, and comprising a first path configured to transmit the driving voltage in a first direction;
a second driving voltage transmission pattern above the first driving voltage transmission pattern, configured to receive the driving voltage, and comprising a second path configured to transmit the driving voltage in the first direction;
a driving voltage line above the second driving voltage transmission pattern, extending in a second direction crossing the first direction, and comprising a connection portion connected to the first driving voltage transmission pattern through a first contact hole and connected to the second driving voltage transmission pattern through a second contact hole; and
a light-emitting element above the driving voltage line.

15. The display device of claim 14, wherein the connection portion of the driving voltage line comprises a first extension portion extending in the first direction and a second extension portion extending in the second direction.

16. The display device of claim 15, wherein the second extension portion is connected to the first driving voltage transmission pattern and to the second driving voltage transmission pattern through the first contact hole and through the second contact hole, respectively.

17. The display device of claim 14, wherein the driving voltage line is provided as a plurality of driving voltage lines spaced apart from each other in the first direction, and
wherein the first driving voltage transmission pattern connects adjacent driving voltage lines.

18. The display device of claim 14, wherein the first driving voltage transmission pattern and the second driving voltage transmission pattern are spaced apart from each other in a plan view.

19. The display device of claim 14, further comprising a capacitor pattern at a same layer as the first driving voltage transmission pattern, spaced apart from the first driving voltage transmission pattern in a plan view, and having capacitance with a portion of the second driving voltage transmission pattern overlapping the capacitor pattern.

20. An electronic device comprising:
a processor configured to transmit an image data signal and an input control signal; and
a display device configured to receive the image data signal and the input control signal, and comprising:
a substrate;
a first driving voltage transmission pattern above the substrate and configured to receive a driving voltage;
a second driving voltage transmission pattern above the first driving voltage transmission pattern, extending in a first direction, and configured to receive the driving voltage;
a driving voltage line above the second driving voltage transmission pattern, extending in a second direction crossing the first direction, and comprising a connection portion connected to the first driving voltage transmission pattern through a first contact hole and connected to the second driving voltage transmission pattern through a second contact hole; and
a light-emitting element above the driving voltage line.
